(19) United States
(12) Patent Application Publication
(10) Pub. No.: US 2023/0030993 A1
(43) Pub. Date: Feb. 2, 2023

(54) MODEL ORDER REDUCTION OF PHYSICAL SYSTEMS

(71) Applicant: Palo Alto Research Center Incorporated, Palo Alto, CA (US)

(72) Inventors: Randi Wang, Mountain View, CA (US); Morad Behandish, San Mateo, CA (US); Ion Matei, Santa Cruz, CA (US)

(73) Assignee: Palo Alto Research Center Incorporated, Palo Alto, CA (US)

(21) Appl. No.: 17/386,674

(22) Filed: Jul. 28, 2021

(51) Int. Cl. G06F 30/20

(52) U.S. Cl. CPC G06F 30/20

(57) ABSTRACT

Methods and systems (e.g., for generating selecting a model-order reduction (MOR) technique and/or level of granularity for a MOR that provide at least one of: (a) flexible cost-accuracy tradeoffs, (b) a priori error bounds, and (c) a priori preservation of properties that provide physical fidelity) may include: providing governing equations for a physical system; defining quantities of interest (QoI) for the physical system; semi-discretizing the governing equations to obtain a full-order model (FOM) using a state-space representation; applying a MOR technique to the FOM to obtain a family of ROMs with different cost and accuracy tradeoffs, wherein each ROM approximates the FOM with respect to the QoI; and selecting one or more preferred ROMs from the family of ROMs based, at least in part, on the cost and accuracy tradeoffs.

### STATEMENT REGARDING FEDERALLY SPONSORED RESEARCH AND DEVELOPMENT

This invention was made with Government support under [G011.3840] DARPA-AIRA-CyPhy and [G011.3875] DARPA-DSO-CompMods. The Government has certain rights in this invention.

### FIELD OF INVENTION

The present disclosure relates to methods and systems for generating selecting a model order reduction (MOR) technique and/or level of granularity for a MOR that provide at least one of: (a) flexible tradeoffs between time cost and accuracy, (b) a priori error bounds, and (c) a priori preservation of properties that provide physical fidelity.

### BACKGROUND

Generally, when encountered with a new physical system, physicists and engineers start by modeling the system as accurately as possible from the first principles. For example, to predict the shape and material properties of an as-manufactured part in liquid metal jet additive manufacturing (AM) process, researchers may first developed a multiphysics model accounting for multiple, simultaneous physical phenomena relating to a metal droplet falling, impacting a surface, solidifying, and coalescing. The resultant numerical simulation required to predict dynamic behaviors of the droplets model is governed by partial differential equations (PDEs). To predict the final shape of products manufactured from such printing processes, the numerical simulation is repeated for each droplet.

However, the numerical simulation for such high-fidelity models (also referred to as full-order models or FOMs) has a high requirement on computation, which is usually too complex and slow, especially at the preliminary design stage where it is usually required to rapidly predict how droplets produce the features of a shape that eventually determine surface quality and dimensional accuracy of printed parts. This is primarily due to the math in which the FOM is based. FOMs typically include partial differential equations (PDEs), partial differential-algebraic equations (PDAEs), or a combination thereof. Returning to the additive manufacturing example, solving PDEs and PDAEs associated with this example is so computationally prohibitive that performing the FOMs would dramatically delay the final shape prediction of the printing process since each droplet takes 20 minutes to 48 hours to simulate, depending on mesh resolution. With a typical mechanical part often requiring millions of droplets to produce, the simulation time can become massive.

One approach to reducing the simulation time is model order reduction (MOR). MOR is a technique that converts PDEs and PDAEs to ordinary differential equations (ODEs) and differential-algebraic equations (DAEs) while preserving the FOM's essential properties and input-output behavior. There are numerous MOR techniques available to users. However, selection of which MOR technique and the level of granularity of the MOR technique is the preference of the user and not necessarily driven by efficiency and efficacy.

### SUMMARY OF INVENTION

The present disclosure relates to methods and systems for generating selecting a MOR technique and/or level of granularity for a MOR that provide at least one of: (a) flexible cost-accuracy tradeoffs, (b) a priori error bounds, and (c) a priori preservation of properties that provide physical fidelity.

The present disclosure includes a method for developing reduced-order models (ROM) of physical systems, the method comprising: providing governing equations for a physical system; defining quantities of interest (QoI) for the physical system; semi-discretizing the governing equations to obtain a full-order model (FOM) using a state-space representation; applying a model-order reduction (MOR) technique to the FOM to obtain a family of ROMs with different cost and accuracy tradeoffs, wherein each ROM approximates the FOM with respect to the QoI; and selecting one or more preferred ROMs from the family of ROMs based, at least in part, on the cost and accuracy tradeoffs.

The present disclosure also includes a method for selecting a model order (MO), the method comprising: providing a full-order (FOM) that comprises state-space equations for a physical system relative to a quantity of interest (QoI); simulating the FOM; recording a time (tₘ) for the FOM to complete; applying a model-order reduction (MOR) technique to the FOM to obtain a family of ROMs with different cost and accuracy tradeoffs; selecting one or more preferred ROMs from the family of ROMs based, at least in part, on the cost and accuracy tradeoffs, wherein each of the one or more preferred ROMs has associated therewith a computation plus simulation time (tₙ); and selecting one or more preferred models from the FOM and the one or more preferred ROMs based, at least in part, on tₘ and tₙ.

The present disclosure further includes systems comprising: a processor; a memory coupled to the processor; and instructions provided to the memory, wherein the instructions are executable by the processor to cause the system to perform one or both of the foregoing methods.

### BRIEF DESCRIPTION OF THE DRAWINGS

The following figures are included to illustrate certain aspects of the disclosure, and should not be viewed as exclusive configurations. The subject matter disclosed is capable of considerable modifications, alterations, combinations, and equivalents in form and function, as will occur to those skilled in the art and having the benefit of this disclosure.

FIG. 1 illustrates a flow diagram of a nonlimiting example method of the present disclosure.

FIG. 2 illustrates a flow diagram of another nonlimiting example method of the present disclosure.

FIG. 3A illustrates a cylinder with one end fixed to the ground and the other end bearing a constant unit pressure (FIG. 3C) used as an example case for the methods and systems described herein. FIG. 3B illustrates one example of a mesh resolution use for the cylinder discretized using second-order tetrahedral finite elements.

FIGS. 4A, 4B, and 4C are illustrations of comparisons between simulation results for FOM and reduced-order models (ROM) for Cases 3, 6, and 9, respectively.

FIG. 5A is a plot (FIG. 5B a zoomed portion of 5A) of the order of the model as a function of simulation time.

FIG. 6A illustrates a bracket bearing a constant unit pressure (FIG. 6C) used as an example case for the methods and systems described herein. FIG. 6B illustrates one example of a mesh resolution use for the bracket discretized using second-order tetrahedral finite elements.

FIG. 7A illustrates a chair bearing a variable unit pressure (FIG. 7C) used as an example case for the methods and systems described herein. FIG. 7B illustrates one example of a mesh resolution use for the chair discretized using second-order tetrahedral finite elements.

### DETAILED DESCRIPTION

The present disclosure relates to methods and systems for generating selecting a MOR technique and/or level of granularity for a MOR that provide at least one of: (a) flexible tradeoffs between time cost and accuracy, (b) a priori error bounds, and (c) a priori preservation of properties that provide physical fidelity.

The methods and systems described herein may combine one or more of (1) spatial discretization schemes to convert distributed models described by PDEs to systems of ODEs or DAEs (or a FOM); (2) projection-based MOR schemes that provide efficient, rigorous, and systematic, providing a priori convergence, stability, and/or error assurances; (3) structure-preserving MOR schemes that preserve certain physical properties; and (4) linearization techniques to generalize (2) and (3) from linear time-invariant systems to nonlinear systems. Such methods and systems may generate a family of models at different levels of granularity that provides users with a “knob” to turn, to navigate the time cost-accuracy trade space with a priori assurances of convergence and stability, a priori error bounds, and/or monotonic improvement.

The methods and systems described herein may seamlessly, systematically, automatically, and/or rapidly generate a family of ROMs by applying rigorous upscaling to the

FOM, which offers the modeling scientist or engineer a spectrum of choices from fast but less accurate to slower but more accurate, depending on which metrics are more important for the application at hand. It enables navigating the time cost-accuracy trade space or guideline as to when and which ROM is a reasonable choice.

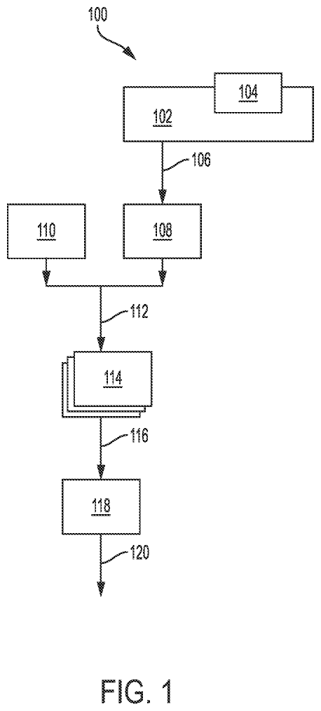

FIG. 1 illustrates a flow diagram of a nonlimiting example method 100 of the present disclosure. In this example, a set of governing equations 102 for a given physical system are provided that relate to a quantity of interest (QoI) 104 of the physical system. That is, the governing equations 102 are the equations that describe the physical system or a portion thereof relative to the QoI 104. For example, a complex set of equations (governing equations) may describe the mechanical motion and deformation, conductive and convective heat transfer, and the phase change due to temperature variations of metal droplets during AM manufacturing processes to give the shape of the metal droplet (QoI) once solidified as part of the object being manufactured. The governing equations 102 may include partial differential equations (PDEs), initial conditions (IC), and boundary conditions (BC). It should be noted that IC and BC values may be equations, explicit values, ranges, or a variant thereof. Therefore, stating that the governing equations include IC and BC does not limit the IC and BC to being equations.

Any physical system may be used including simple systems like a pendulum swinging, a truss structure bearing pressure, a chair bearing pressure, a bike frame bearing pressure, or a simple circuit to complex systems like an airplane engine, a polymer synthesis reactor, vehicle suspension system, oven, power inverter, or a ventricular assist device. Further, physical system, unless otherwise specified, when use herein encompasses an entire physical system or a portion thereof. For example, the physical system may be a vehicle engine, the combustion system of a vehicle engine, or a single piston within the engine (e.g., where the QoI may be the movement of said piston). Examples of physical systems to which the methods of the present disclosure may be applied include, but are not limited to, a chemical synthesis reactor; a distillation column; an automobile engine; heating, ventilation, and air conditioning (HVAC) systems; robots (e.g., for modeling robot dynamics, robot parts, robot part interactions, and the like); vehicles (e.g., for modeling vehicle dynamics, vehicle parts, vehicle part interactions and the like); electrical networks; distribution network systems; thermodynamic systems; and the like.

In the example method 100, the governing equations 102 are semi-discretized 106 to yield a full order model 108. Semi-discretizing 106 may involve a state-space representation where the equations are discretizes in space while leaving time as a continuum. For example, semi-discretizing 106 may comprise a parameterization of the spatial domain (e.g., a 3D domain represented in a computer-aided design (CAD) software) and spatial discretization (e.g., type, topology, and size parameters for a 3D conforming or non-conforming mesh). Therefore, every spatio-temporal field, representing physical quantities that are distributed in space and varying in time, is projected onto a finite but large number of temporal signals (i.e., functions of time), where each signal often represents variations of some (global or local) integral properties of the original physical quantities that are sufficient to reproduce the fields up to an acceptable accuracy. The result is a system of ODEs or DAEs in terms of these signals. This system of ODEs or DAEs are referred to herein as full order models (FOMs).

Examples of spatial discretization schemes that can be applied for the step of semi-discretizing 106 may include, but are not limited to, finite difference, finite volume, finite element, spectral basis, isogeometric analysis, other methods that fall under Galerkin projections using conforming on non-conforming mesh, meshless methods (e.g., particle-based or lumped parameter models, and the like.

The FOMs 108 produced from semi-discretizing 106 are likely very large (e.g., tens to hundreds of thousands of equation and unknowns, if no millions) depending on the discretization resolution (e.g., mesh element size). Such large FOMs 108 are difficult, if not impossible, to solve numerically within a reasonable time frame.

The method 100 then includes applying a MOR technique 112 to convert the FOM 108 to a family of smaller ODE/DAE system(s) (hereafter called family of ROMs 114) whose solutions approximate that of FOM 108 with different time cost-accuracy tradeoffs. Examples of MOR techniques 112 include, but are not limited to, a projection-based MOR (e.g., a Petrov-Galerkin projection, a Bubnov-Galerkin projection, and a symplectic projection), a balanced truncation, and a Krylov subspace method.

In the illustrated example method 100, a priori conditions 110 are defined (e.g., by a user) that are used to restrict the one or more aspects of the MOR technique 112. For example, the a priori conditions 110 may include bounds on error (e.g., 1-norm error, 2-norm error, and infinity-norm error, and p-norm error where p can be any positive value) between the FOM and the ROM). Alternatively or additionally, the a priori conditions 110 may include preservation of desired physical structure (e.g., Hamiltonian) and/or properties (e.g., convergence and stability) between the FOM and the ROM.

The time cost-accuracy tradeoff is generally a dual measure of how much computing time it takes to perform a specific ROM within the family of ROMS 114 and how accurate said ROM is relative to data. Said data may be experimental data, simulated data, calculated data from closed-form solutions, and the like, and any combination thereof. The simulated data may be from a high-fidelity physical model (e.g., the governing equations 102 and/or the FOM 108). The time cost-accuracy tradeoff provides a metric by which one or more preferred ROMs from the family of ROMs 114 may later be chosen. Additional metrics that may be considered when choosing one or more preferred ROMs is the extent to which the a priori conditions 110 are fulfilled.

Examples of MOR techniques 112 include, but are not limited to, a Krylov subspace method (e.g., such a method based on CUmulative REduction (CURE) scheme), balanced truncation (BT) method, rational Krylov subspace (RKS) method, iterative rational Krylov algorithm (IRKA), model truncation method, and the like.

The methods and systems described herein may use the family of ROMs 114 in a plurality of ways. In the illustrated example, one or more preferred ROMs 118 are selected 116 from the family of ROMs 114 based on (a) the time cost-accuracy tradeoff and/or (b) the extent to which the a priori conditions 110 are fulfilled (e.g., (b1) being within the a priori error bounds and/or (b2) preservation of the selected a priori properties, preferably said properties that provide physical fidelity of the ROM 118 to the physical system and/or governing equations 102).

The one or more preferred ROMs 118 may then be implemented 120 relative to the physical system, for example, as models for controlling the operation, diagnosing issues, and prognosticating conditions within a physical system. When more than one preferred ROM 118 is implemented, the output of said ROMs may be compared where diverging results may indicate (or cause) the user to repeat the process for to improve the fidelity of the ROM(s) being implemented 120.

Generally, a controller for a physical system includes models for various QoI for a physical system. Further, the controller may act as a mediator between a user and models thereof. In one example, a user inputs to a controller a condition of the physical system to be changed (e.g., the catalyst input rate of a polymerization reactor), the controller manipulates the physical system (e.g., the polymerization reactor) and inputs data to the model of a QoI, and the controller reports the QoI (or related value) in response to the change to the physical system to the user (e.g., via a display).

In an example regarding controlling the operation of the physical system, a controller may be derived that uses and/or is based on one or more preferred ROMs 118 derived and chosen by the methods and/or systems describe herein.

In an example regarding prognosticating conditions, models similar to the controller may be derived that use and/or are based on one or more preferred ROMs 118 derived and chosen by the methods and/or systems describe herein where theoretical parameters of the physical system (e.g., future system parameter settings) may be input and the corresponding system conditions output. Individual system conditions may have thresholds which inform the extent to which individual system parameters may be changed to stay within the bounds of the thresholds.

In an example regarding diagnosis of the physical system, a diagnosis engine may be derived that uses and/or is based on one or more preferred ROMs 118 derived and chosen by the methods and/or systems describe herein. The diagnosis engine can use causal analysis based on constraint satisfaction to detect and isolate faults in the system.

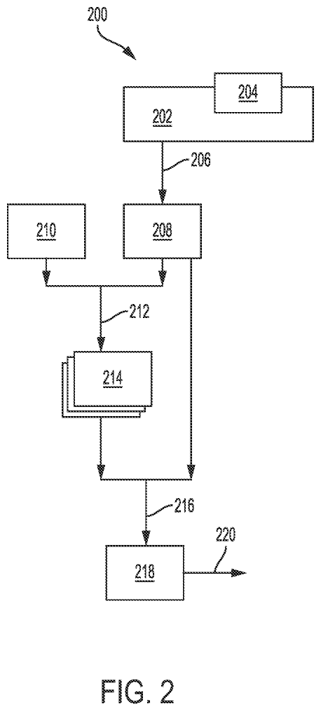

FIG. 2 illustrates a flow diagram of another nonlimiting example method 200 of the present disclosure. In the example method 200, a set of governing equations 202 for a given physical system are provided that relate to a QoI 204 of the physical system. The governing equations 202 are semi-discretized 206 to yield a FOM 208. The method 200 then includes applying a MOR technique 212 to convert the FOM 208 to a family of ROMs 214 whose solutions approximate that of FOM 208 with different time cost-accuracy tradeoffs. The a priori conditions 110 may be defined (e.g., by a user) that are used to restrict the one or more aspects of the MOR technique 112. The foregoing described in the example method 200 overlap with steps described relative to FIG. 1, the description of said FIG. 1 steps apply to those of FIG. 2.

In the illustrated method 200, the FOM 208 and family of ROMs 214 (or one or more preferred ROMs, which may be determined as described in FIG. 1) are compared 216 to determine which will take less time to arrive at a solution. One nonlimiting example is perform such a comparison is to derive plot of (a) the simulation time (tₘ) as a function of order of the FOM 208 and (b) the reduction plus simulation time (tₙ) as a function of each of the family of ROMs 214 (or one or more preferred ROMs). A comparison 216 of these two plots may be used to determine one or more preferred models 218 for implementation 220 (e.g., any of the implementations 120 described relative to FIG. 1). The one or more preferred models 218 may be the FOM 208, one or more ROMs from the family of ROMs (or one or more preferred ROMs), or both the FOM 208 and the one or more ROMs from the family of ROMs (or one or more preferred ROMs). As described relative to FIG. 1 when the preferred models 218 includes two or more models, the models may be compared over time to identify diverging results that may indicate (or cause) the user to repeat the process for to improve the fidelity of preferred models 218 being implemented 220.

An alternative method for comparing 216 the FOM 208 and family of ROMs 214 (or one or more preferred ROMs) is to choose (or determine) an order for the one or more preferred models 218 and calculate the simulation time (tₘ) and reduction plus simulation time (tₙ), respectively. Then, the one or more preferred models 218 may be chosen based on said times, where preferred models likely take the least amount of time.

In the method 200, the FOM 208 and family of ROMs 214 (or one or more preferred ROMs) may have the same or different numerical integration method. Examples of numerical integration methods include, but are not limited to, a forward and backward Euler method, a mid-point method, a Runge Kutta method, an Adams-Bashforth method, and a variational method.

The methods described herein may, and in many embodiments must, be performed, at least in part, using computing devices or processor-based devices that include a processor; a memory coupled to the processor; and instructions provided to the memory, wherein the instructions are executable by the processor to perform the methods described herein (such as computing or processor-based devices may be referred to generally by the shorthand “computer”).

“Computer-readable medium” or “non-transitory, computer-readable medium,” as used herein, refers to any non-transitory storage and/or transmission medium that participates in providing instructions to a processor for execution. Such a medium may include, but is not limited to, non-volatile media and volatile media. Non-volatile media includes, for example, NVRAM, or magnetic or optical disks. Volatile media includes dynamic memory, such as main memory. Common forms of computer-readable media include, for example, a floppy disk, a flexible disk, a hard disk, an array of hard disks, a magnetic tape, or any other magnetic medium, magneto-optical medium, a CD-ROM, a holographic medium, any other optical medium, a RAM, a PROM, and EPROM, a FLASH-EPROM, a solid state medium like a memory card, any other memory chip or cartridge, or any other tangible medium from which a computer can read data or instructions. When the computer-readable media is configured as a database, it is to be understood that the database may be any type of database, such as relational, hierarchical, object-oriented, and/or the like. Accordingly, exemplary embodiments of the present systems and methods may be considered to include a tangible storage medium or tangible distribution medium and prior art-recognized equivalents and successor media, in which the software implementations embodying the present techniques are stored.

For example, a system may comprise: a processor; a memory coupled to the processor; and instructions provided to the memory, wherein the instructions are executable by the processor to cause the system to: defining quantities of interest (QoI) for a physical system; semi-discretize governing equations for the physical system to obtain a full-order model (FOM) using a state-space representation; apply a model-order reduction (MOR) technique to the FOM to obtain a family of ROMs with different cost and accuracy tradeoffs, wherein each ROM approximates the FOM with respect to the QoI; and select one or more preferred ROMs from the family of ROMs based, at least in part, on the cost and accuracy tradeoffs.

In another example, a system may comprise: a processor; a memory coupled to the processor; and instructions provided to the memory, wherein the instructions are executable by the processor to cause the system to: simulating a full-order (FOM) that comprises state-space equations for a physical system relative to a quantity of interest (QoI); recording a time (tₘ) for the FOM to complete; applying a model-order reduction (MOR) technique to the FOM to obtain a family of ROMs with different cost and accuracy tradeoffs; selecting one or more preferred ROMs from the family of ROMs based, at least in part, on the cost and accuracy tradeoffs, wherein each of the one or more preferred ROMs has associated therewith a computation plus simulation time (tₙ); and selecting one or more preferred models from the FOM and the one or more preferred ROMs based, at least in part, on tₘ and tₙ.

### EXAMPLE EMBODIMENTS

A first nonlimiting example embodiment of the present disclosure is a method for developing reduced-order models (ROM) of physical systems, the method comprising: providing governing equations for a physical system; defining quantities of interest (QoI) for the physical system; semi-discretizing the governing equations to obtain a full-order model (FOM) using a state-space representation; applying a model-order reduction (MOR) technique to the FOM to obtain a family of ROMs with different cost and accuracy tradeoffs, wherein each ROM approximates the FOM with respect to the QoI; and selecting one or more preferred ROMs from the family of ROMs based, at least in part, on the cost and accuracy tradeoffs.

A second nonlimiting example embodiment of the present disclosure is a system comprising: a processor; a memory coupled to the processor; and instructions provided to the memory, wherein the instructions are executable by the processor to cause the system to perform the method of first nonlimiting example embodiment.

The first and/or second nonlimiting example embodiments may further include one or more of: Element 1: wherein the governing equations comprise partial differential equations (PDEs), initial conditions (IC), and boundary conditions (BC), and wherein the semi-discretization converts the governing equations to ordinary differential equations (ODEs) or differential-algebraic equations (DAEs); Element 2: Element 1 and wherein the semi-discretization is a spatial discretization using a method selected from the group consisting of: a finite different method, a finite volume method, a finite element method, a finite cell method, a cell method, a boundary element method, a spectral method, a mimetic method, a particle-based method, and any hybrid thereof; Element 3: wherein the MOR technique is selected from the group consisting of: a projection-based MOR, a balanced truncation, and a Krylov subspace method; Element 4: Element 3 and wherein the projection-based MOR technique is selected from the group consisting of: a Petrov-Galerkin projection, a Bubnov-Galerkin projection, and a symplectic projection; Element 5: the method further comprising: defining a priori conditions, wherein applying the MOR technique to the FOM includes staying within the a priori conditions; Element 6: Element 5 and wherein the a priori conditions comprise (a) bounds on error between the FOM and the ROM and/or (b) preservation of a physical structure and/or properties between the FOM and the ROM; Element 7: Element 6 and wherein error is selected from the group consisting of: 1-norm error, 2-norm error, infinity-norm error, and p-norm error where p can be any positive value; Element 8: the method further comprising: modeling the QoI of the physical system with the one or more preferred ROMs; Element 9: the method further comprising: operating the physical system using a controller that incorporates the one or more preferred ROMs; Element 10: the method further comprising: changing a parameter of the physical system using a controller that incorporates the one or more preferred ROMs; and Element 11: the method further comprising: prognosticating conditions of the physical system using the one or more preferred ROMs. Examples of combinations include, but are not limited to, Element 1 (optionally in combination with Element 2) in combination with one or more of Elements 3-11; Element 3 (optionally in combination with Element 4) in combination with one or more of Elements 5-11; Element 5 (optionally in combination with Element 6 or Elements 6 and 7) in combination with one or more of Elements 8-11; and two or more of Elements 8-11 in combination.

A third nonlimiting example embodiment of the present disclosure is a method for selecting a model order (MO), the method comprising: providing a full-order (FOM) that comprises state-space equations for a physical system relative to a quantity of interest (QoI); simulating the FOM; recording a time (tₘ) for the FOM to complete; applying a model-order reduction (MOR) technique to the FOM to obtain a family of ROMs with different cost and accuracy tradeoffs; selecting one or more preferred ROMs from the family of ROMs based, at least in part, on the cost and accuracy tradeoffs, wherein each of the one or more preferred ROMs has associated therewith a computation plus simulation time (tₙ); and selecting one or more preferred models from the FOM and the one or more preferred ROMs based, at least in part, on tₘ and tₙ.

A fourth nonlimiting example embodiment of the present disclosure is a system comprising: a processor; a memory coupled to the processor; and instructions provided to the memory, wherein the instructions are executable by the processor to cause the system to perform the method of third nonlimiting example embodiment.

The third and/or fourth nonlimiting example embodiments may further include one or more of: Element 12: wherein the FOM simulations and the ROM simulations are performed using the same numerical integration method; Element 13: Element 12 and wherein the numerical integration method is selected from the group consisting of: a forward and backward Euler method, a mid-point method, a Runge Kutta method, an Adams-Bashforth method, and a variational method; and Element 14: the method further comprising: defining a priori conditions, wherein applying the MOR technique to the FOM includes staying within the a priori conditions.

Unless otherwise indicated, all numbers expressing quantities of ingredients, properties such as molecular weight, reaction conditions, and so forth used in the present specification and associated claims are to be understood as being modified in all instances by the term “about.” Accordingly, unless indicated to the contrary, the numerical parameters set forth in the following specification and attached claims are approximations that may vary depending upon the desired properties sought to be obtained by the incarnations of the present inventions. At the very least, and not as an attempt to limit the application of the doctrine of equivalents to the scope of the claim, each numerical parameter should at least be construed in light of the number of reported significant digits and by applying ordinary rounding techniques.

One or more illustrative incarnations incorporating one or more invention elements are presented herein. Not all features of a physical implementation are described or shown in this application for the sake of clarity. It is understood that in the development of a physical embodiment incorporating one or more elements of the present invention, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for those of ordinary skill in the art and having benefit of this disclosure.

While compositions and methods are described herein in terms of “comprising” various components or steps, the compositions and methods can also “consist essentially of” or “consist of” the various components and steps.

To facilitate a better understanding of the embodiments of the present invention, the following examples of preferred or representative embodiments are given. In no way should the following examples be read to limit, or to define, the scope of the invention.

### EXAMPLES

Three geometric objects (a cylinder, a bracket, and a chair) with linear elastic material properties undergoing dynamic mechanical loads to illustrate the methods and systems described herein. The shapes are arbitrary, and the method is applicable as long as the geometry can be tessellated (i.e., conforming mesh) or immersed in a background grid (i.e., non-conforming mesh, as in immersed boundary methods). The boundary conditions in these examples are fixed displacement at some surfaces and uniform pressure at other surfaces, but can be anything in general. Particularly, the cylinder example is mainly used to explain the general idea behind the methods and systems described herein because said example is a simple shape and the closed-form response to uniform loading (i.e., the ground truth) is known and intuitively well-understood. The other two examples (bracket and chair) are presented with different boundary conditions. In general, the method works for arbitrary shapes, material properties, and initial/boundary conditions. More general embodiments can be obtained by straightforward extension to different domains of physics (or coupled mutli-physics), linear and nonlinear constitutive/material laws, and geometric representations.

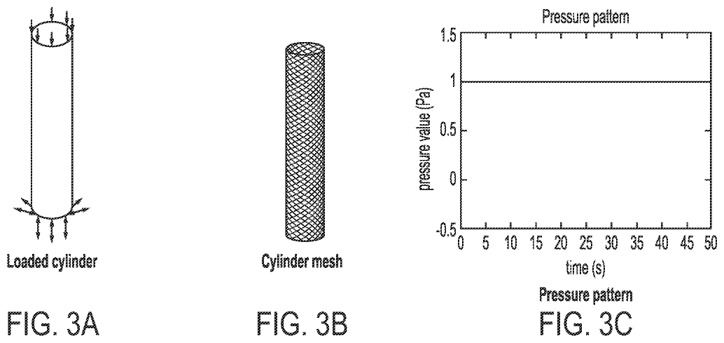

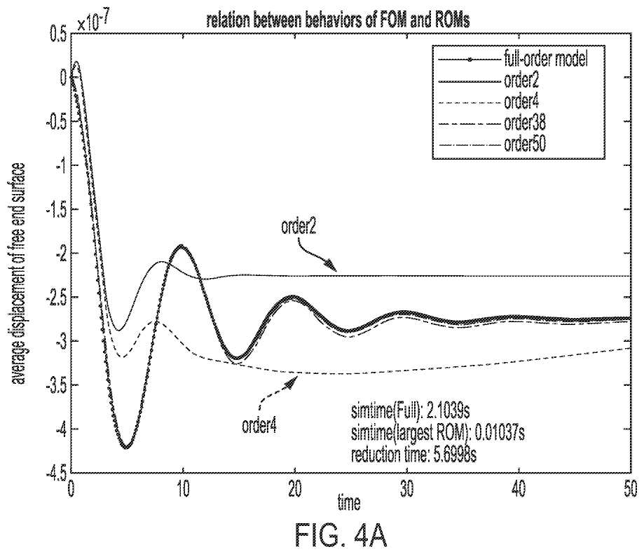

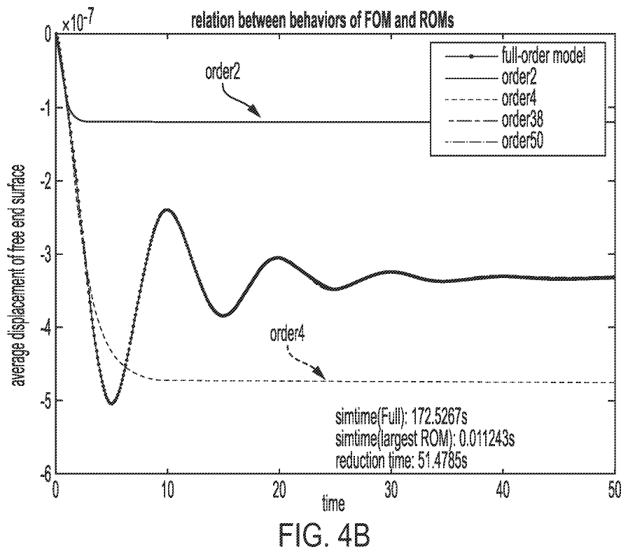

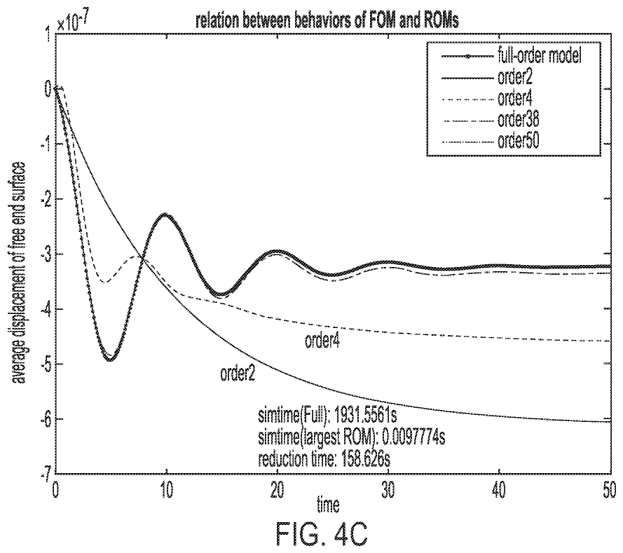

Example 1. This example presents the results of MOR applied to a finite element analysis (FEA) model of the cylinder (FIG. 3A) with one end fixed to the ground and the other end bearing a constant unit pressure (FIG. 3C). The cylinder is discretized using second-order tetrahedral finite elements with nine different mesh resolutions (only one sketch is shown in FIG. 3B), from which nine groups of governing equations were generated whose number of variables ranges from around 600 to 18,000. By applying the CURE framework embedded by the SPARK algorithm, nine families of ROMs were obtained for each of the nine cases starting from the lowest model order of k=2 and iteratively increasing the model order to k=50. The simulation results for FOM and ROM are compared, where the abscissa represents the physical time and the ordinate represents the average displacement of the free end of the cylinder. FIGS. 4A, 4B, and 4C are illustrations of such comparisons for Cases 3, 6, and 9, respectively. Only a few ROM curves are labeled due to the limited white space. From these nine figures, it can be observed that as the MO of ROM increases, the simulated response of the ROM gradually approaches that of the FOM. Table 1 provides three durations of time for each of the nine cases: (1) the FOM simulation running time; (2) the ROM simulation running time for model order k=50; and (3) the total reduction time to obtain ROM of model order k=50.

TABLE 1

| | | ROM simulation | Total reduction time to |
|---|---|---|---|
| | FOM simulation | running time for model | obtain ROM of model |
| | running time (s) | order k = 50 (s) | order k = 50 (s) |
| Case 1 | 0.277 | 0.010 | 1.771 |
| Case 2 | 0.755 | 0.010 | 2.909 |
| Case 3 | 2.104 | 0.010 | 5.700 |
| Case 4 | 9.391 | 0.011 | 13.285 |
| Case 5 | 69.724 | 0.010 | 31.858 |
| Case 6 | 172.527 | 0.011 | 51.479 |
| Case 7 | 415.126 | 0.011 | 68.523 |
| Case 8 | 945.259 | 0.011 | 125.089 |
| Case 9 | 1931.556 | 0.010 | 158.626 |

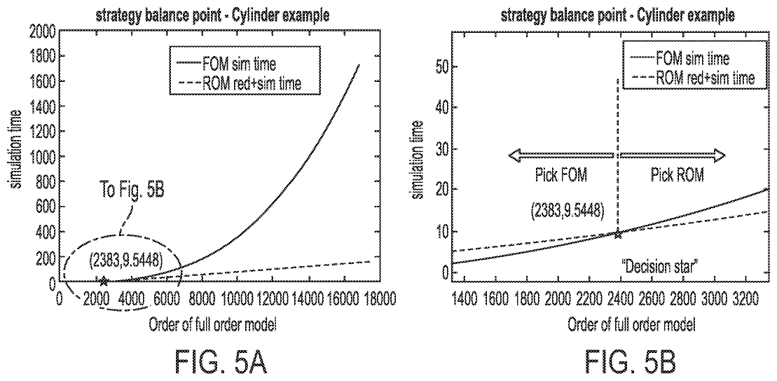

Linear or polynomial regression may be used to fit the relationship between computation time and FOM order (i.e., number of original state variables). The solver used was built in the Matlab “sparse state space (sss)” toolbox, which can be used to analyze dynamical systems with state-space dimensions O (10⁴) or higher. Particularly, the solver can preserve the sparsity of large-scale models and take advantage of it for computations (e.g., using sparse LU decompositions) that would otherwise be computationally expensive or even infeasible. It was observed that if the FOM is directly simulated using this solver with the backward Euler method, the relationship is quadratic in FIG. 5. However, if the MOR is first performed using the SPARK+CURE approach, generate the ROM of model order k=50 and then simulate the ROM using the same solver with the backward Euler method, the relation between simulation time and model order (of the original FOM) appears linear in FIG. 5. Particularly, in this cylinder and the other tow examples (bracket and chair), the eventual ROM order of k=50 was pre-defined by the user, although in practice it should be determined by the tolerance on errors, using the a priori error bounds.

For all families of ROMs obtained starting from different FOM orders, we verified that as the ROM order was increased to 50 using the CURE scheme, the relative H2—errors between FOM and ROM remained less than 3%. It can be observed from FIG. 9 that the slope of the linear relationship between simulation running time and the initial FOM order is only around 0.01, which means that for every 10 thousand-fold increase of the FOM order, the MOR time to obtain the family of ROM for model orders k=2, 3, . . . , 50 increases by about 100 seconds.

In addition, we can find a cross-over point on these two fitted relation curves, where the total time (reduction time plus simulation of ROM) equals the simulation time of FOM. The position of this point implies that if the FOM order is less than 2383, then direct simulation of the FOM would have a lower computational cost (i.e., running time). Otherwise, conducting MOR first before simulation would have a lower cost. However, the saving in running time comes at the expense of accuracy. Three different measures of error owing to the MOR process were investigated; namely, the relative H₂—error of the transfer functions, the steadystate error (SSE), and the root-mean-squared error (RMSE) of the overall output. The user can select an upper-bound on the H₂—error that can be tolerated for their specific modeling application, and a new cross-over point (perhaps slightly shifted towards larger FOM orders) is obtained from the a priori error bound computed by the CURE algorithm. However, the current embodiment does not provide rigorous a priori bounds on SSE and RMSE, nor does it guarantee a strictly monotonic decay of these errors by increasing the ROM order in the cumulative reduction process, although an overall reduction pattern is commonly observed.

In addition to the CURE scheme, the BT method was also investigated relative to Cases 1-3 for comparison. Both of methods obtained good approximations. Table 2 provides the reduction time for k=30 for each case.

TABLE 2

| | CURE reduction time k = 30 (s) | BT reduction time k = 30 (s) |
|---|---|---|
| Case 1 | 1.087 | 2.78 |
| Case 2 | 1.807 | 17.221 |
| Case 3 | 3.317 | 73.04 |

As illustrated, the BT method takes much longer time than the CURE scheme, because the BT method relies on solving full-scale Lyapunov equations, which is quite time consuming, while the CURE framework only relies on fast matrix multiplication and matrix decomposition operations.

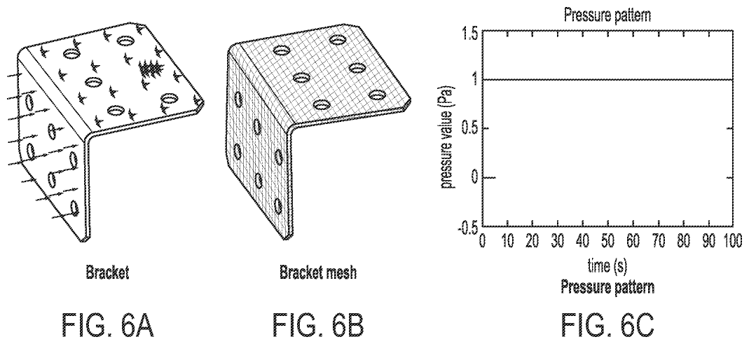

Example 2. This example investigates a bracket model with one surface fixed while the other surface bears constant unit pressure (FIG. 6A-6C). Similar to the cylinder of Example 1, the geometry was discretized using tetrahedral finite elements with different resolutions and then the CURE scheme was used to obtain a family of ROMs for each case, with model orders ranging from k=2 to k=50. In this example, if the FOM is larger than k=3871 simulating the ROM is more efficient.

The SSE, RMSE, and relative H₂—error bounds for the bracket example. The SSE is less than 1% for all the three cases. The RMSE is O(10⁻¹⁰-O(10⁻⁸)), which is several orders of magnitude smaller than FOM output of O(10⁴). The a priori H₂—error bound results show that if the ROM order is larger than 50, then the exact relative H₂—error would be less than 10^{2.1603}≈0.69%.

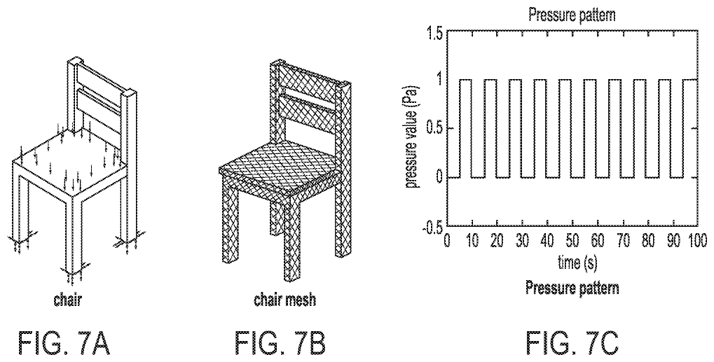

Example 3. This example investigates a bracket model with one surface fixed while the other surface bears constant unit pressure (FIG. 7A-7C). Similar to the cylinder of Example 1, the geometry was discretized using tetrahedral finite elements with different resolutions and then the CURE scheme was used to obtain a family of ROMs for each case, with model orders ranging from k=2 to k=50.

The SSE, RMSE, and relative H₂—error bounds for the bracket example. The SSE is less than 1% for all the three cases. The RMSE is O(10⁻⁹-O(10⁻⁸)), which is several orders of magnitude smaller than FOM output of O(10⁻⁴). The a priori H₂—error bound results show that if the ROM order is larger than 50, then the exact relative H₂—error would be less than 10^{-1.7725}≈1.69%.

Therefore, the present invention is well adapted to attain the ends and advantages mentioned as well as those that are inherent therein. The particular examples and configurations disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative examples disclosed above may be altered, combined, or modified and all such variations are considered within the scope and spirit of the present invention. The invention illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

The invention claimed is:

1. A method for developing reduced-order models (ROM) of physical systems, the method comprising:
providing governing equations for a physical system;
defining quantities of interest (QoI) for the physical system;
semi-discretizing the governing equations to obtain a full-order model (FOM) using a state-space representation;
applying a model-order reduction (MOR) technique to the FOM to obtain a family of ROMs with different cost and accuracy tradeoffs, wherein each ROM approximates the FOM with respect to the QoI; and
selecting one or more preferred ROMs from the family of ROMs based, at least in part, on the cost and accuracy tradeoffs.

2. The method of claim 1, wherein the governing equations comprise partial differential equations (PDEs), initial conditions (IC), and boundary conditions (BC), and wherein the semi-discretization converts the governing equations to ordinary differential equations (ODEs) or differential-algebraic equations (DAEs).

3. The method of claim 2, wherein the semi-discretization is a spatial discretization using a method selected from the group consisting of: a finite different method, a finite volume method, a finite element method, a finite cell method, a cell method, a boundary element method, a spectral method, a mimetic method, a particle-based method, and any hybrid thereof

4. The method of any preceding claim, wherein the MOR technique is selected from the group consisting of: a projection-based MOR, a balanced truncation, and a Krylov subspace method.

5. The method of claim 4, wherein the projection-based MOR technique is selected from the group consisting of: a Petrov-Galerkin projection, a Bubnov-Galerkin projection, and a symplectic projection.

6. The method of claim 1 further comprising:
defining a priori conditions, wherein applying the MOR technique to the FOM includes staying within the a priori conditions.

7. The method of claim 6, wherein the a priori conditions comprise (a) bounds on error between the FOM and the ROM and/or (b) preservation of a physical structure and/or properties between the FOM and the ROM.

8. The method of claim 7, wherein error is selected from the group consisting of: 1-norm error, 2-norm error, infinity-norm error, and p-norm error where p can be any positive value.

9. The method of claim 1 further comprising:
modeling the QoI of the physical system with the one or more preferred ROMs.

10. The method of claim 1 further comprising:
operating the physical system using a controller that incorporates the one or more preferred ROMs.

11. The method of claim 1 further comprising:
changing a parameter of the physical system using a controller that incorporates the one or more preferred ROMs.

12. The method of claim 1 further comprising:
prognosticating conditions of the physical system using the one or more preferred ROMs.

13. A method for selecting a model order (MO), the method comprising:
providing a full-order (FOM) that comprises state-space equations for a physical system relative to a quantity of interest (QoI);
simulating the FOM;
recording a time (tₘ) for the FOM to complete;
applying a model-order reduction (MOR) technique to the FOM to obtain a family of ROMs with different cost and accuracy tradeoffs;
selecting one or more preferred ROMs from the family of ROMs based, at least in part, on the cost and accuracy tradeoffs, wherein each of the one or more preferred ROMs has associated therewith a computation plus simulation time (tₙ); and
selecting one or more preferred models from the FOM and the one or more preferred ROMs based, at least in part, on tₘ and tₙ.

14. The method of claim 13, wherein the FOM simulations and the ROM simulations are performed using the same numerical integration method.

15. The method of claim 14, wherein the numerical integration method is selected from the group consisting of: a forward and backward Euler method, a mid-point method, a Runge Kutta method, an Adams-Bashforth method, and a variational method.

16. The method of claim 13 further comprising:
defining a priori conditions, wherein applying the MOR technique to the FOM includes staying within the a priori conditions.
